(19) United States
(12) Patent Application Publication
(10) Pub. No.: US 2009/0273392 A1
(43) Pub. Date: Nov. 5, 2009

(54) METHODS AND APPARATUS FOR REDUCING NON-IDEAL EFFECTS IN CORRELATED DOUBLE SAMPLING COMPENSATED CIRCUITS

(75) Inventors: Oleg Korobeynikov, Swampscott, MA (US); Joseph M. Kulinets, North Andover, MA (US); Vladimir Protasov, Revere, MA (US); Peter R. Nuytkens, Melrose, MA (US)

Correspondence Address: GOODWIN PROCTER LLP;PATENT ADMINISTRATOR, 53 STATE STREET, EXCHANGE PLACE, BOSTON, MA, 02109-2881, US

(73) Assignee: Custom One Design, Inc., Meelrose, MA (US)

(21) Appl. No.: 12/113,731

(22) Filed: May 1, 2008

(51) Int. Cl. H03K 5/00

(52) U.S. Cl. 327/551

(57) ABSTRACT

Embodiments of the present invention address kT/C noise, sampled high frequency operational amplifier noise, and charge injection errors sampled on switching capacitors and introduced due to internal switching. Correlated double sampling compensates for DC offset and low frequency operational amplifier noise, and the use of fake integration and a capacitor divider eliminate or significantly reduce kT/C noise, sampled high frequency operational amplifier noise, and charge injection errors.

### CROSS-REFERENCE TO RELATED APPLICATIONS

This application is related to and claims the benefit of the U.S. patent application bearing Docket No. COD-005, entitled “Apparatus for Current-to-Voltage Integration for Current-to-Digital Converter” and filed contemporaneously herewith, which is hereby incorporated by reference as if set forth in its entirety herein.

### FIELD OF THE INVENTION

The present invention relates to methods and apparatus for reducing DC offset and low-frequency noise in correlated double sampling compensated circuits.

### BACKGROUND OF THE INVENTION

Many important electronic devices, such as voltage amplifiers, ADC and DAC stages, integrators and filters, sample-and-hold (S/H) circuits, analog delay stages, and comparators, etc., are designed using methods and techniques to compensate for non-ideal effects of the operational amplifiers used, including noise (mainly thermal and 1/f noise), input-referred DC offset voltage, and a non-ideal virtual ground at the input of the operational amplifier (“op-amp”) resulting from the op-amp's finite gain. Reducing the low-frequency noise and offset at the op-amp input increases the dynamic range and accuracy of the circuit. Reducing the signal voltage at the virtual ground terminal reduces the effect of the finite low-frequency gain of the op-amp on the signal-processing characteristics of the stage. Both improvements are significant in linear integrated circuits fabricated in a low-voltage CMOS technology as the reduction of dynamic range caused by DC offset and low-frequency amplifier noise becomes increasingly significant and cascoding may not be a practical circuit option due to the resulting reduction of the output signal swing.

In linear active circuits, the active element most often used is the operational amplifier (“op-amp”), whose main function in the circuit is to create a virtual ground, i.e., a node with a zero (or constant) voltage at the op-amp's input terminal without sinking any current. Using op-amps with MOS input transistors, the op-amp input current at low frequencies can indeed be made extremely small. However, the input voltage of a practical op-amp is usually significantly large (typically on the order of 1-10 mV), since it is affected by several non-ideal effects. These effects include noise (i.e., 1/f and thermal noise), the input-referred dc offset voltage, and the signal voltage needed to generate the desired output voltage from the op-amp.

Normally, the thermal noise occupies a wide frequency band, while the 1/f noise, offset and input signal are narrowband low-frequency signals. The three basic techniques that are used to reduce the offset and low-frequency noise of op-amps are the correlated double sampling (CDS), autozero, and chopper stabilization techniques. These techniques are applicable to such important building blocks as voltage amplifiers, ADC and DAC stages, integrators and filters, sample-and-hold (S/H) circuits, analog delay stages, and comparators.

The basic idea of CDS is sampling the low-frequency noise and offset values and then subtracting the sampled values from the instantaneous value of the influenced signal. The CDS process requires at least two phases: a sampling phase, at the end of which the offset voltage and the noise voltage are sampled and stored, and a signal-processing phase, during which the offset-free op-amp is available for operation. In most practical implementations, during the sampling phase the amplifier is disconnected from the signal path and switched into an appropriate feedback configuration (for example, a unity-gain configuration), and its inputs are short-circuited and set to an appropriate common-mode voltage. The offset is eliminated using the control parameter, such as the voltage obtained across the CDS capacitor after the amplifier has settled. This control parameter is next sampled and stored, for example, as a voltage at the CDS capacitor. After this, the offset-compensated op-amp is available for amplification and is connected again to the signal path during the signal-processing phase.

One consequence of sampling offset and low-frequency noise is that upon opening the switch that short-circuits the op-amp during the sampling phase, a thermal noise (i.e., kT/C noise) is also sampled on the CDS capacitor. Thermal noise arises from the random motion of free electrons in a conductive medium. Each free electron inside the medium is in motion due to its thermal energy. Since capacitors are noiseless devices, the capacitors used in sampling circuits do not have any thermal noise associated with their operation. However, thermal noise will be present in the switch or the amplifier used in the sampling operation. The sampled thermal noise introduces undesired voltage errors into the sampled voltage.

The integrated thermal noise power of a sampling circuit is the product of the thermal noise spectral density and the thermal noise bandwidth of the circuit. When a switch is used in a sample and hold operation, the thermal noise spectral density and the thermal noise bandwidth are calculated in part based on the on-resistance of the switch. When an amplifier is used in the sample and hold operation, the thermal noise spectral density and the thermal noise bandwidth are calculated in part based on the transconductance of the amplifier. In conventional sampling circuits, the spectral density and the bandwidth of the thermal noise are dominated by the same element, for example, the switch or the amplifier of the sampling circuit.

When the integrated thermal noise power is calculated, the result is kT/C, where k is Boltzmann's constant, T is the ambient temperature, and C is the capacitance of the sampling capacitor. The sampling of the kT/C noise together with DC offset and 1/f noise introduces additional error during a signal-processing phase, because the sampled value of the kT/C noise is also involved into CDS compensation process. Although the capacitance of the CDS capacitor can be increased to reduce the sampled kT/C noise, a large capacitance is undesirable because it requires a longer sampling phase and greater power consumption.

Accordingly, there is a need for a CDS architecture that employs advanced methods for the reduction of kT/C noise, sampled high frequency operational amplifier noise, charge injection errors and other errors that could be introduced during the sampling cycle of CDS.

### SUMMARY OF THE INVENTION

Embodiments of the present invention provide a new method of fighting kT/C noise and charge injection errors sampled on switching capacitors introduced due to the switching of internal switches in the circuitry. This\\this method almost completely eliminates the errors induced by kT/C noise, sampled high frequency operational amplifier noise, charge injection errors, with accuracy limited to the errors introduced by the finite gain of the operational amplifier of the integrator.

As will be evident from the detailed description below, embodiments of the current invention use correlated double sampling to compensate for DC offset and low frequency op-amp noise, and also use new methods of fake integration and using a capacitor divider to eliminate or significantly reduce kT/C noise, sampled high frequency operational amplifier noise, charge injection errors, which emerge during internal switch opening and are sampled by CDS capacitors. Such reduction takes place in all cases when any switch in the circuitry is opened and kT/C noise is sampled on a capacitor.

The fake integration phase involves the integration of sampled kT/C noise on a capacitor separate from the main integrating capacitor. This fake integration capacitor is a low capacitance value capacitor coupled in a special arrangement together with the so called noise load capacitor and a switch. To eliminate kT/C and charge injection errors generated and sampled on the main CDS capacitor during the CDS noise sampling phase, the additional capacitors are first connected so that the fake integration capacitor is connected as an integrating capacitor, converting the circuit into an integrator and integrating the kT/C induced error charge on the fake integration capacitor. Next, the switch opens and returns the fake integration circuit into its original configuration. Opening the switch at this moment also produces kT/C noise, the value of which is mostly determined by the capacitance of the noise load capacitor that is significantly large. This noise is sampled by the serially connected fake integration capacitor and other capacitors connected in parallel at the inverting input of op-amp. Since the capacitance value of the fake integration capacitor is significantly less than the capacitance value of the total capacitance at the inverting input of op-amp, the dominant part of the error voltage will be distributed across the fake integration capacitor, significantly reducing the kT/C induced errors on CDS capacitor.

As a result the magnitude of attenuated kT/C noise at the inverting input of the op-amp (i.e., V_{akTC}) will be equal to:

V_{akTC}=V_{kTC}/K,

where V_{kTC} is a value of kT/C noise at the terminal of the switch, and K is the division ratio of the capacitive divider:

K=C_{II}/C_{N}

and C_{II} is the total capacitance at the inverting input of op-amp. For different embodiments of current invention C_{II} has different values. Similarly the values of sampled high frequency noise at output of operational amplifier and charge injection errors will be reduced K-fold.

As discussed, the fake integration phase mostly eliminates large kT/C noise introduced at the end of the sampling phase by the opening of the switch putting the circuit into an appropriate feedback configuration (for example, in a unity-gain configuration) during the sample phase. The magnitude of this noise at the inverting input of the op-amp (i.e., V_{akTC}) was comparably large. During the fake integration phase, the integration of this noise resulted in the change of the output voltage of the op-amp by:

ΔV_{FI}=V_{akTC}*K

If the op-amp was ideal and had infinite gain, this change in the output voltage would have no influence on the CDS process. But since the op-amp has finite gain G, this will result in the introduction of the additional error voltage accumulated on the Cl, capacitance at the end of the fake integration phase, which is equal to:

ΔV_{ER}=ΔV_{FI}/G=V_{akTC}*K/G

By choosing the parameters of the circuit such a way that K/G<<1 the value of the error introduced by kT/C noise can be significantly reduced.

Therefore it is seen that by employing fake integration the value of the error voltage introduced by opening the switch at the end of the sampling phase can be reduced in G/K time. The kT/C noise introduced by opening the switch which configures the integrator for fake integration is attenuated in K time by the capacitive divider.

In another embodiment, additional rounds of the fake integration process are used. As a result of every additional fake integration the additional error voltage accumulated on the CD C_{II} capacitance at the end of the nth fake integration phase ΔV_{ER}(n) will be reduced to

ΔV_{ER}(n)=V_{ER}(n−1)*K/G

where ΔV_{ER}(n−1) is the additional error voltage accumulated on the CII capacitance at the end of the preceding fake integration phase. For example, as a result of first additional fake integration the additional error voltage accumulated on the CII capacitance at the end of the first additional fake integration will be equal to:

ΔV_{ER1}=ΔV_{ER}*K/G=V_{akTC}*(K/G)²

Each additional sub-phase of fake integration must be preceded by an additional fake integration capacitor reset sub-phase. During the fake integration capacitor reset sub-phase, the fake integration capacitor is reset by shorting it with a special switch. The opening of this switch does not introduce any kT/C error into the voltage on the capacitor(s) forming the C_{II} capacitance.

In one aspect, embodiments of the present invention provide a method for reducing non-ideal effects in correlated double sampling compensated circuits. The method includes providing a circuit including an operational amplifier; putting that circuit in an auto-zeroing configuration; sampling a signal comprising a sum of low frequency noises, high frequency noises, and a constant offset in connection with a sampling phase of a correlated double sampling operation; putting the circuit in a fake integration configuration and performing a fake integration, removing the high frequency noises from the sum; and putting the circuit in a signal processing configuration and simultaneously performing the second phase of the correlated double sampling operation to remove the low frequency noises and the constant offset from a produced output signal.

In one embodiment, putting the circuit in an auto-zeroing configuration includes putting the circuit in a unity-gain feedback configuration. In another embodiment, putting the circuit in an auto-zeroing configuration includes putting the circuit in an error-sampling configuration. In still another embodiment, putting the circuit in a signal processing configuration includes the generation of thermal high frequency noise.

In yet another embodiment, providing a circuit comprising an operational amplifier includes providing a circuit includes an operational amplifier, a first capacitor used for sampling, a second capacitor used for fake integration, and a switch for putting the circuit into the fake integration configuration. In another embodiment, putting the circuit into the signal processing configuration produces a thermal noise that is attenuated by a capacitor divider formed by the first capacitor and the second capacitor.

In another aspect, embodiments of the present invention provide a method for reducing non-ideal effects in correlated double sampling compensated circuits. The method includes providing a circuit comprising an operational amplifier, a first capacitor used for sampling, a second capacitor for fake integration, and a switch for putting the circuit into a fake integration configuration; putting the circuit in an auto-zeroing configuration; sampling a signal comprising a sum of low frequency noises, high frequency noises, and a constant offset in connection with a sampling phase of a correlated double sampling operation; putting the circuit into the fake integration configuration and performing a fake integration, removing the high frequency noises from the sum; resetting the second capacitor; putting the circuit in the fake integration configuration and performing the fake integration; and putting the circuit in a signal processing configuration and simultaneously performing the second phase of the correlated double sampling operation to remove the low frequency noises and the constant offset from a produced output signal. In one embodiment, the method further includes the iteration of the steps of resetting the second capacitor and putting the circuit in the fake integration configuration and performing the fake integration.

In yet another aspect, embodiments of the present invention provide a circuit including an input terminal, an output terminal, and an operational amplifier having an inverting input, a non-inverting input, a ground terminal, and an output in electrical communication with the output terminal; a first switch having a first terminal in electrical communication with the input terminal of the circuit and a second terminal; a second switch having a first terminal in electrical communication with the non-inverting input of the operational amplifier and a second terminal in electrical communication with the ground terminal; a first capacitor for a correlated double sampling operation having a first terminal in electrical communication with the non-inverting input of the operational amplifier and a second terminal in electrical communication with the second terminal of the first switch; a third switch having a first terminal in electrical communication with the output of the operational amplifier and a second terminal; and a second capacitor for fake integration having a first terminal in electrical communication with the non-inverting input of the operational amplifier and a second terminal in electrical communication with the second terminal of the third switch.

In one embodiment, the value of the second capacitor for fake integration is substantially smaller than the value of the first capacitor for the correlated double sampling operation. In another embodiment, the circuit includes a third capacitor for reducing the thermal noise from the opening of the third switch, the third capacitor having a first terminal in electrical communication with the second terminal of the second capacitor and a second terminal in electrical communication with the ground terminal. In one embodiment, the value of the third capacitor is substantially larger than the value of the second capacitor.

In yet another embodiment, the circuit includes a fourth switch having a first terminal in electrical communication with the first terminal of the second capacitor and a second terminal in electrical communication with the second terminal of the second capacitor. In another embodiment, the circuit is operated as a correlated double sampling compensated operational amplifier. In yet another embodiment, the circuit is operated as a correlated double sampling compensated switching capacitors inverting amplifier. In still another embodiment, the circuit is operated as a correlated double sampling compensated switched capacitor integrator.

The foregoing and other features and advantages of the present invention will be made more apparent from the description, drawings, and claims that follow.

### BRIEF DESCRIPTION OF DRAWINGS

The advantages of the invention may be better understood by referring to the following drawings taken in conjunction with the accompanying description in which:

FIG. 1 depicts a flowchart of a prior art correlated double sampling method used for eliminating DC offset and low-frequency 1/f noise in electronic circuits;

FIG. 2 shows a flowchart of one correlated double sampling method in accord with the present invention that significantly reduces kT/C and charge injection noise by opening switches between the auto-zeroing (sampling) and signal-processing phases;

FIG. 3 depicts a flowchart of another correlated double sampling method in accord with the present invention that significantly reduces kT/C and charge injection noise by opening switches between the auto-zeroing (sampling) and signal-processing phases and additionally addressing non-ideality errors during the fake integration phase;

FIGS. 4A and 4B are a block diagram of a prior art operational amplifier using CDS for DC offset and 1/f noise elimination in different phases of operation. FIG. 4A presents the op-amp in Error Sampling Phase, and FIG. 4B presents the op-amp in Signal-Processing Phase;

FIGS. 5A-5D present a block diagram of one embodiment of an operational amplifier in accord with the present invention in different phases of operation, with all switches shown in position at the beginning of the respective phase (see Table 1). FIG. 5A presents the op-amp in Error Sampling Phase, FIG. 5B presents the op-amp in a Fake Integration Phase, FIG. 5C presents the op-amp in Capacitive Division Noise Elimination, and FIG. 5D presents the op-amp in a Signal-Processing Phase;

FIGS. 6A and 6B are a block diagram of a prior art switched capacitor operational amplifier using CDS for DC offset and 1/F noise elimination in different phases of operation. FIG. 6A presents the op-amp in Reset Phase, and FIG. 6B presents the op-amp in Amplification Phase;

FIGS. 7A-7D present a block diagram of one embodiment of a switched capacitor operational amplifier using CDS for DC offset and 1/f noise elimination in accord with the present invention in different phases of operation, with all switches shown in position at the beginning of the respective phase (see Table 2). FIG. 7A presents the op-amp in Reset Amplifier Phase, FIG. 7B presents the op-amp in a Fake Integration Phase, FIG. 7C presents the op-amp in Capacitive Division Noise Elimination, and FIG. 7D presents the op-amp in an Amplification Phase;

FIGS. 8A-8C present a block diagram of a prior art switched capacitor integrator using CDS for DC offset and 1/f noise elimination in different phases of operation. FIG. 8A presents the switched capacitor integrator in Initial Reset Phase, FIG. 8B presents the switched capacitor integrator in Integration Phase, and FIG. 8C presents the switched capacitor integrator in Reset Phase;

FIGS. 9A-9G present a block diagram of one embodiment of a switched capacitor integrator using CDS for DC offset and 1/f noise elimination in accord with the present invention in different phases of operation, with all switches shown in position at the beginning of the respective phase (see Table 3). FIG. 9A presents the op-amp in Initial Reset Phase, FIG. 9B presents the op-amp in an Initial Fake Integration Phase, FIG. 9C presents the op-amp in an Initial Capacitive Division Noise Elimination, FIG. 9D presents the op-amp in an Integration Phase, FIG. 9E presents the op-amp in a Reset Phase, FIG. 9F presents the op-amp in a Fake Integration Phase, and FIG. 9G presents the op-amp in Capacitive Division Noise Elimination; and

FIGS. 10A-10C present a block diagram of another enhancement to switched capacitor integrator using CDS for DC offset and 1/f noise elimination in accord with another embodiment of present invention in different sub-phases of Initial Multiple Fake Integration Phase. FIG. 10A presents the switched capacitor integrator in Initial Multiple Fake Integration sub-Phases, FIG. 10B presents the switched capacitor integrator in Initial Capacitive Division Noise Elimination states, and FIG. 10C presents the switched capacitor integrator in Initial. Multiple Fake Integration Reset sub-Phases.

### DETAILED DESCRIPTION OF THE INVENTION

In most practical implementations of CDS, during the sampling phase the circuit is disconnected from the signal path and switched into an appropriate feedback configuration (for example, a unity-gain configuration). In the feedback configuration, the inputs are short-circuited and set to an appropriate common-mode voltage. Any voltage offset is eliminated using the control parameter, such as the voltage obtained across the CDS capacitor after the circuit has settled. This control parameter is sampled and stored, again for example, as a voltage at the CDS capacitor. After this sampling phase, the offset-compensated circuit is available for operation and is connected again to the signal path for a signal-processing phase.

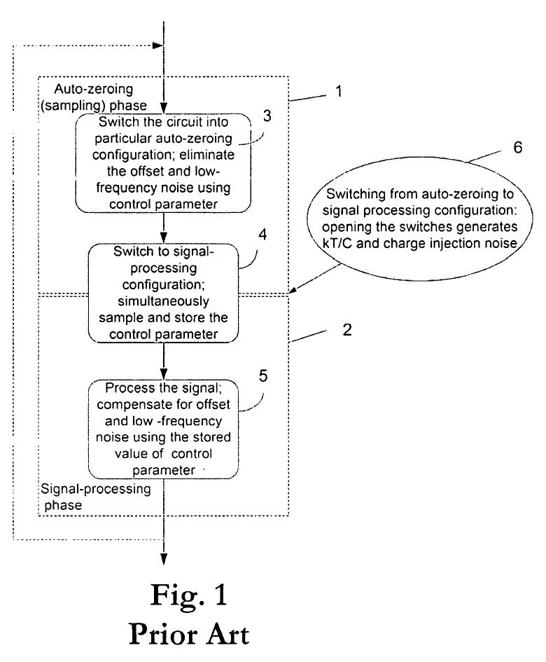

FIG. 1 shows a flowchart of a known correlated double sampling method commonly used for eliminating DC offset and low-frequency 1/f noise in electronic circuits. The basic CDS method is implemented in two distinct phases. Referring to FIG. 1, during the first auto-zeroing phase (Step 1) the circuit using CDS compensation is switched into an auto-zeroing configuration, for example, into a feedback unity-gain configuration. This configuration allows for the auto-zeroing of the circuit by changing a control parameter, for example, a control voltage at a particular node of the circuit. When the auto-zeroing process is settled, the value of this control parameter is stored. Then the circuit is switched into the signal-processing phase (Step 2) and the offset and internal noise of the circuit are compensated using the stored value of the control parameter.

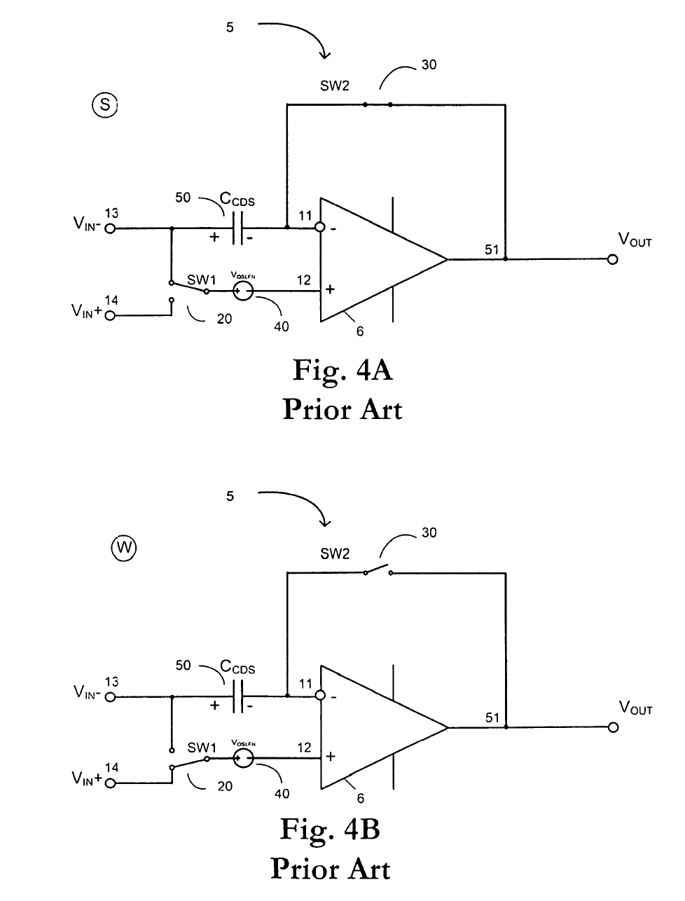

This basic process can be illustrated in an exemplary prior art amplifier circuit, such as that presented in FIGS. 4A and 4B. FIGS. 4A and 4B show a high gain amplifier that is CDS compensated and samples the amplifier's offset and 1/f noise in a closed-loop configuration.

With reference to FIGS. 4A and 4B, the amplifier circuit 5 contains the operational amplifier op-amp 6. For simplicity, we will assume that the op-amp 6 is close to ideal, having infinite gain and infinite input impedance, but still having DC offset and internal low frequency noise. FIGS. 4A and 4B conditionally show the low-frequency noise 1/f, thermal noise, and offset of op-amp 6 as the voltage source V_{OSLFN} 40 connected between the non-inverting input 12 of op-amp 6 and the first common terminal of switch SW1 20. The second and third terminals of switch SW1 50 are connected directly to the negative 13 and positive 14 inputs of the circuit 5, respectively. The inverting input 11 of op-amp 6 is connected to CDS capacitor C_{CDS} 50 and to the first terminal of feedback switch SW2 30. The second terminal of CDS capacitor C_{CDS} 50 is connected to the second terminal of switch SW1 20. The output 51 of op-amp 6 is connected to the second terminal of switch SW2 30.

During the auto-zeroing phase, depicted in FIG. 4A, the op-amp 6 is disconnected from the signal path and connected in a unity-gain configuration by closing the switch SW2 30. Assuming the op-amp 6 has infinite gain, the voltage V_{CDS} obtained across the CDS capacitor C_{CDS} after the op-amp 6 has settled is equal to the sum of the offset voltage and low-frequency 1/f noise of op-amp 6 V_{OSLFN} . This voltage represents the control parameter mentioned above. This configuration of circuit 5 reflects Step 3 of FIG. 1

The circuitry is then switched to the signal-processing configuration (Step 4 of FIG. 1), most often by first switching the circuit from the auto-zeroing configuration. Simultaneously the operation of sample-and-hold is performed for the control parameter. While switching from the auto-zeroing configuration, the opening of the switch generates a kT/C noise (Step 6 of FIG. 1).

The second phase of CDS, the signal-processing phase (Step 2 of FIG. 1) starts with switching the circuitry into the signal-processing configuration. During the signal-processing phase, the DC offset and 1/f noise value is recreated using the hold value of the control parameter and subtracted from the instantaneous value of the influenced signal (Step 5 of FIG. 1).

The opening of the switches during the reconfiguration of the circuit from the auto-zeroing to the signal-processing configuration generates kT/C thermal noise (Step 6 of FIG. 1). The power value of this noise depends on the value of the capacitors adjacent to the particular switch and can be significant. This value directly influences the value of the control parameter, which is sampled-and-held. During the signal-processing phase, the recreated value of the DC offset and 1/f noise will be corrupted with value of the kT/C noise existing at the moment of sampling. While the DC offset and the kT/C noise will be compensated, the additional sampled voltage value introduced by sampling kT/C will be erroneously involved in the compensation process, introducing error into the signal path during the signal-processing phase.

With reference to FIGS. 4A and 4B, opening the switch SW2 30 and, after a small delay, switching SW1 20 in another position puts the circuit into the signal-processing configuration. As a result, the voltage across CDS capacitor C_{CDS} 50 is sampled and stored on capacitor C_{CDS} . This combined error is equal to the sum of the offset voltage and the low-frequency 1/f noise of op-amp 6 (i.e., V_{OSLFN} ), plus an additional error from thermal noise kT/C_{CDS} and the charge injection error q_{ing}/C_{CDS} occurring when switch SW2 opens. The combined error charge will remain trapped on capacitor C_{CDS} since the input current of op-amp 6 is zero (assuming infinite input impedance), and hence capacitor C_{CDS} behaves like a floating voltage source equal to V_{OSLFN} plus the kT/C and charge-injection error. If the op-amp 6 is not ideal and has a finite gain, the residual offset is nearly equal to the original offset divided by the amplifier dc gain.

In the signal-processing phase, the offset-compensated amplifier is available for amplification and is connected again to the signal path, as shown in FIG. 4B. The sampled value of kT/C noise in this configuration appears on the CDS capacitor 50 in addition to the V_{OSLFN} and introduces additional error to the output of the op-amp 6. The op-amp 6 in the signal-processing phase can be, in general, connected in a closed-loop configuration for amplification and in an open-loop configuration when it is used as a comparator. In the scheme described above, the amplifier is not available to the external circuitry during the offset sampling phase. This is not a major drawback for most applications. If continuous-time amplification is required, the offset-free amplifier can be duplicated and used in a time-shared (“ping-pong”) operation or the continuous-time feed forward technique may be used.

### Exemplary Method Embodiment

As discussed above, embodiments of the present invention provide methods to compensate for the kT/C and charge injection errors generated and sampled during the sampling of CDS noise by providing the compensation value only for the DC offset and low-frequency 1/f noise during the signal-processing phase, with the kT/C value eliminated.

Methods in accord with the present invention add an additional switching phase to the two main phases of the known CDS method. This new phase is colloquially referred to as “fake integration” and follows the switching of the circuit from the auto-zeroing phase and the generation of kT/C noise from the opening the auto-zeroing configuration switch, which is sampled on the CDS capacitor together with DC offset and 1/f noise. In this phase, the circuitry is configured as an integrator that zeroes down the main circuit using “fake” integration. This integration phase essentially repeats the auto-zeroing process at the input of the circuit, but the control parameter is determined not by settling unity-gain, but by settling integrator configuration. This integration phase is “fake,” integrates kT/C noise only and does not involve a useful signal. To enable the fake integration stage, a special low capacitance value capacitor is provided in a circuit.

During the fake integration phase this fake integration capacitor is connected as an integrating capacitor. The fake integration capacitor is coupled with the second noise load capacitor and a special switch, which, when open, rearranges the circuitry reestablishing the signal-processing configuration. The fake integration capacitor is reset (i.e., completely discharged) during the auto-zeroing phase and is charged as the integration of kT/C induced error charge takes place. During the fake integration phase, the DC offset and low frequency 1/f noise do not change their value in comparison with the auto-zeroing phase, and are not involved in fake integration. This fake integration essentially eliminates the kT/C induced error.

After the completion of fake integration, the above-mentioned switch reconfigures the fake integration circuit into the original circuit configuration. Opening this switch at this moment also produces kT/C noise. The error voltage resulting from kT/C noise is determined by the value of the noise load capacitor that is connected in parallel with the fake integration capacitor. The value of the noise load capacitor is relatively large, so the induced kT/C voltage is relatively small. That error voltage is sampled by the serially-connected CDS capacitor and fake integration capacitor and split inversely according to the capacitance ratio of the capacitors. Since the capacitance value of the fake integration capacitor is significantly less than the capacitance value of the CDS capacitor, the dominant part of the error voltage will be distributed across the fake integration capacitor, significantly reducing the kT/C induced errors on CDS capacitor.

With the circuitry in the signal-processing phase, as with the known CDS method, the CDS capacitor is now influencing the path of the input signal, and the voltage stored on it compensates for DC offset and 1/f noise, but contrary to the prior art CDS method, the kT/C noise is eliminated from this voltage.

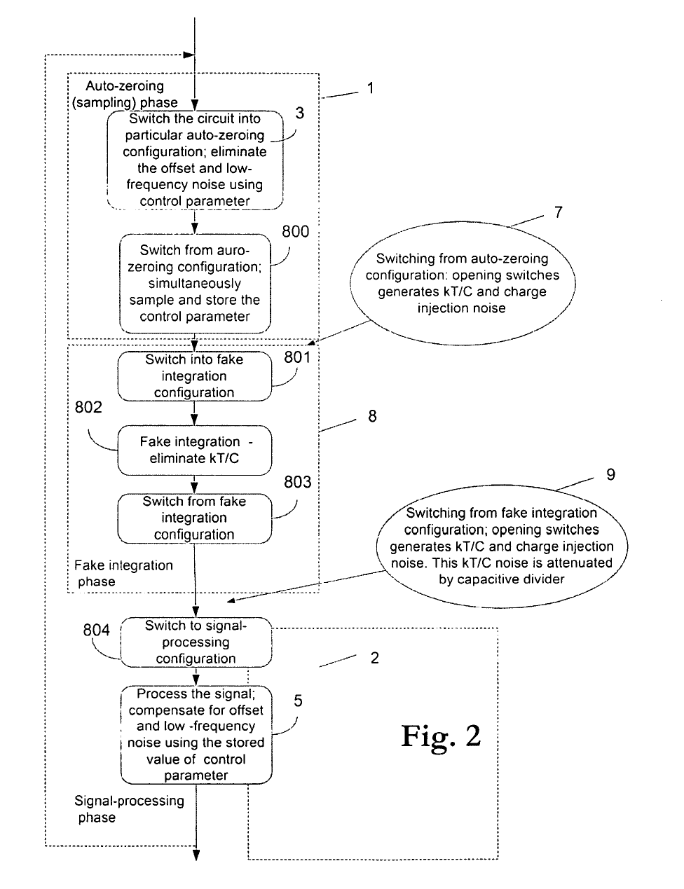

FIG. 2 is a flowchart presenting an embodiment of a method in accord with the present invention. This embodiment is intended for circuits where the control parameter is a voltage that is a derivative of the sum of the DC offset and 1/f noise voltages and is sampled-and-held on a CDS capacitor.

During the auto-zeroing (i.e., sampling) phase (Step 1 of FIG. 2) the noise-compensated circuit is switched into an auto-zeroing configuration, for example, into a feedback unity-gain configuration. This configuration should allow for the auto-zeroing of the circuit by changing a particular control parameter, for example, a control voltage at particular node of the circuit. Using this control parameter, the circuit is auto-zeroed (Step 3 of FIG. 2), and as a result the offset and internal noise of the circuit are compensated.

With further reference to FIG. 2, the circuitry is then switched from auto-zeroing configuration (Step 800 of FIG. 2) by opening the switch that, while closed, forms the auto-zeroing configuration of the circuit. As discussed above, opening this switch generates kT/C noise (Step 7 of FIG. 2).

Next the circuit is switched to the fake integration phase (Step 8 of FIG. 2). This step can be performed simultaneously with switching from the auto-zeroing phase, in which case Steps 800 and 801 will be combined, or sequentially, as depicted in FIG. 2. During the fake integration phase (Step 802 of FIG. 2) the kT/C voltage is integrated and essentially eliminated from control parameter (e.g., the voltage on the CDS capacitor).

At the end of the fake integration phase (Step 8 of FIG. 2), the circuitry is switched from the fake integration configuration (Step 803 of FIG. 2). Opening the switch to take the circuit out of the fake integration configuration generates kT/C noise (Step 9 of FIG. 2). The error voltage generated by kT/C noise is determined by the value of the noise load capacitor that is connected in parallel with the fake integration capacitor. The value of the noise load capacitor is relatively large, so the induced kT/C voltage is relatively small. That error voltage is sampled by serially connected CDS capacitor and fake integration capacitor and split inversely to the capacitance ratio of capacitors. Because the capacitance value of the fake integration capacitor is significantly less than the capacitance value of the CDS capacitor, the majority of the error voltage will be distributed across the fake integration capacitor, significantly reducing the kT/C induced errors on CDS capacitor.

The circuitry is now in the signal-processing phase (Step 2 of FIG. 2). As with the known CDS method, the CDS capacitor is now influencing the path of the input signal, and the voltage stored on it compensates for DC offset and 1/f noise, but in contrast to the prior art CDS method, the kT/C noise is eliminated from this voltage (Step 5 of FIG. 2).

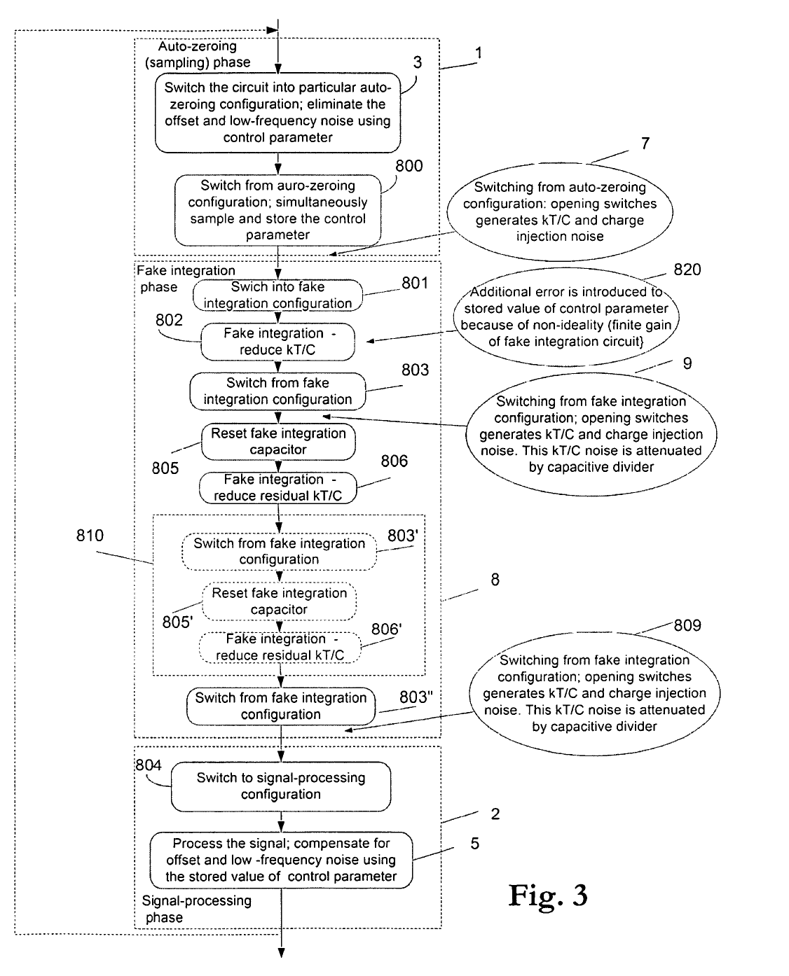

FIG.3 presents another embodiment of the proposed method which helps eliminate the error introduced into the fake integration process from the finite gain of op-amp. It was shown above that since the op-amp has finite gain G, this will result in the introduction of an additional error voltage at the end of the fake integration phase equal to:

ΔV_{ER}=V_{akTC}*K/G

In another embodiment of the proposed method, additional rounds of the fake integration process are used. As a result, after the nth fake integration the additional error voltage accumulated on the Cl, capacitance at the end of the nth additional fake integration will be equal to:

ΔV_{ER1}=V_{akTC}*(K/G)ⁿ

Each additional sub-phase of fake integration is preceded by an additional fake integration capacitor reset sub-phase. During the fake integration capacitor reset sub-phase, the fake integration capacitor is reset by shorting it with a special switch.

The method shown in FIG. 3 is essentially similar to the method shown in FIG.2 except for the additional steps 805-806 and the optional additional steps combined in block 810 that may be either omitted or repeated one or more times.

At step 805 the voltage across the fake integration capacitor is reset to zero in preparation for the next round of fake integration. This step is followed by additional fake integration (step 806), which reduces the residual sampled kT/C by K/G as shown above. The sequence of additional fake integration rounds shown in block 810 can be continued. As FIG. 3 shows, each round (step 810) comprises switching from fake integration configuration (step 803′) followed by resetting fake integration capacitor (step 805′) and fake integration (step 806′). After the optional last round (step 810) the circuitry switches from fake integration configuration at step 803″.

### Exemplary Circuit Embodiment—Operational Amplifier

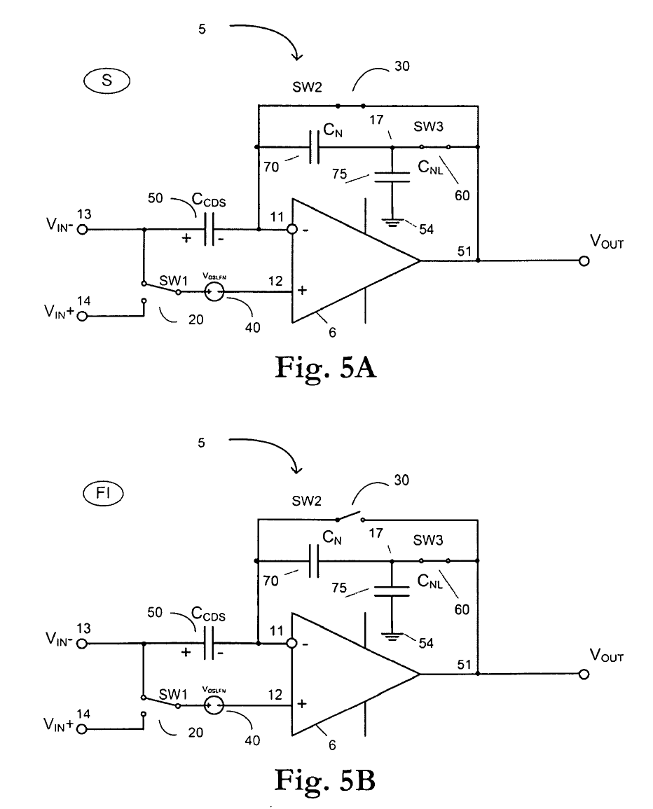

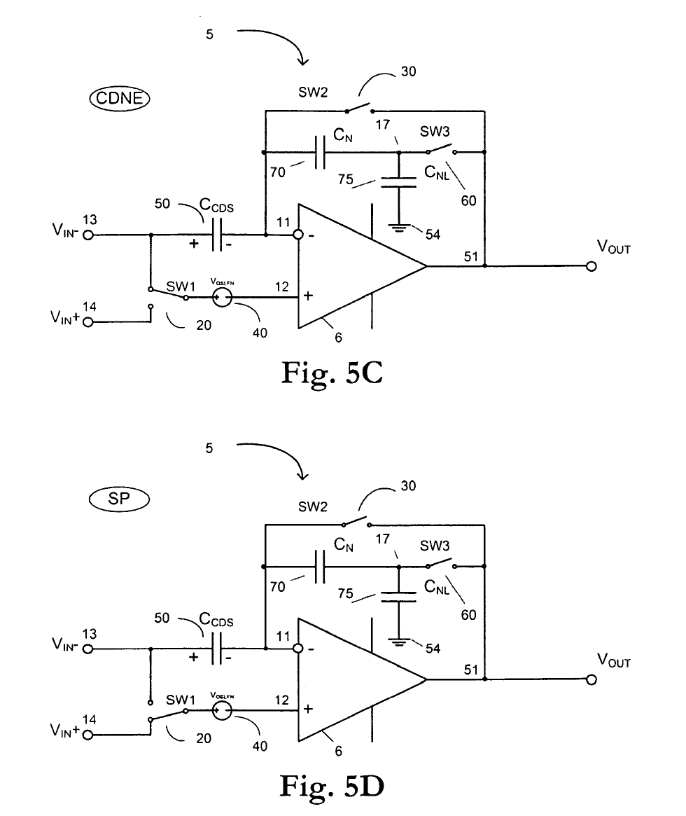

FIGS. 5A-5D present one embodiment of a circuit using an operational amplifier in accord with the present invention in its different phases of operation. These figures follow FIGS. 4A-4B with the following additions. First, the output 51 of op-amp 6 is coupled by switch SW3 60 to node 17, which is connected to a “fake” integrating capacitor C_{N} 70 and to one plate of “noise load” capacitor C_{NL} 75. The other plate of “noise load” capacitor C_{NL} 75 is connected to node 54 which is at ground potential. Capacitor C_{NL} 75 is used to reduce the kT/C noise generated at node 17 during the opening of switch SW3 60. Capacitor C_{N} 70 together with CDS capacitor C_{CDS} 50 forms a capacitive divider, which attenuates the kT/C noise generated at node 17 while transmitting it to the node 11. The attenuation ratio is approximately determined by the ratio of the capacitance of C_{N} to the input capacitance of op-amp 6 at node 11 (that for ideal op-amp 6 equals that of C_{CDS} 50). The capacitance values for capacitors C_{N} 70 and C_{NL} 75 shown in FIGS. 5A-5D can have different values. For the sizable attenuation of kT/C noise generated at node 17 the following conditions should be observed:

C_{N}<<C_{NL};

C_{N}<<C_{CDS}.

For example, the value of capacitor C_{N} 70 can be in the range from 0.1 pF to 20 pF, and the value of capacitor C_{NL} 75 can be from 10 pF to 200 pF.

During regular operation, circuit 5 FIGS. 5A-5D is switching among different phases in the following repeating order: auto-zeroing, fake integration, signal-processing, auto-zeroing, and so on. Table 1, below, depicts the position of the switches during different phases of the operation of circuit 5. When a switch is in the ON state it is closed, when it is in the OFF state it is open.

TABLE 1

Switches Position

| | SW1 | SW2 | SW3 |
|---|---|---|---|
| Error Sampling Phase | UP | ON | ON |
| Fake Integration Phase | UP | OFF | ON |
| Capacitive Division Noise | UP | OFF | OFF |
| Elimination | | | |
| Signal-Processing Phase | DOWN | OFF | OFF |

FIG. 5A shows the operational amplifier 6 in auto-zeroing configuration. The switch SW3 60 is closed. The switch SW2 30 is closed, which brings the op-amp 6 into unity-gain configuration.

Assuming that op-amp 6 has an infinite gain, the voltage V_{CDS} obtained across the CDS capacitor C_{CDS} 50 after op-amp 6 has settled is equal to the sum of the offset voltage and low-frequency 1/f noise of op-amp 6 (i.e., V_{OSLFN} ). This voltage represents the control parameter mentioned above in the description of FIG. 2.

At the end of the auto-zeroing phase switch SW2 30 is open, and operational amplifier 5 is switched into the fake integration configuration shown in FIG. 5B. As a result, the voltage across CDS capacitor C_{CDS} 50, which is equal to the sum of the offset voltage and low-frequency 1/f noise of op-amp 6 (i.e., V_{OSLFN} ) plus an additional error from thermal noise kT/C_{CDS} and charge injection error q_{ing}/C_{CDS} occurring when switch SW2 30 opens, is sampled and stored on capacitor C_{CDS} . The combined error charge will remain trapped on capacitor C_{CDS} since the input current of op-amp 6 is zero (assuming infinite input impedance for the op-amp). Therefore capacitor C_{CDS} behaves like a floating voltage source equal to V_{OSLFN} plus the kT/C and charge-injection error.

The output of the op-amp 6 during fake integration phase is connected to its inverting input 11 through noise capacitor C_{N} 70, putting op-amp 6 in an integrator configuration with the capacitor C_{N} 70 serving as an integrating capacitor. Noise load capacitor C_{NL} 75 is connected as a capacitive load to the output of the integrator.

The main goal of the fake integration phase is the elimination of kT/C noise, sampled high frequency noise at the output of op-amp 6, and charge injection noise, which were all sampled during the opening of switch SW2 30 at the beginning of fake integration phase, while leaving CDS capacitor C_{CDS} 50 still charged to the value of the main low frequency noises of op-amp 6: i.e., 1/f noise and DC offset as they were sampled at the beginning of the fake integration phase.

During the fake integration phase, op-amp 6 is in an integrator configuration, where capacitor C_{N} 70 plays the role of an integrating capacitor. At the beginning of the fake integration phase, the voltage difference between the inverting input 11 and non-inverting input 12 of the op-amp 6 is equal to the sampled value of the sum of DC offset, 1/f noise, kT/C noise, high-frequency noises at the output of op-amp 6, and charge injection error. Assuming that op-amp 6 has an infinite gain, at the end of the fake integration phase, the voltage difference between the inverting input 11 and non-inverting input 12 of op-amp 6 will be equal to the sampled value of the sum of DC offset and 1/f noise (i.e., V_{OSLFN} ). This essentially eliminates the additional error voltage related to the sampled kT/C noise, high-frequency noises at the output of op-amp 6, and charge injection error at node 11.

At the end of the fake integration phase the error voltage at node 11 on CDS capacitor C_{CDS} 50 is related only to the sum of the DC offset voltage and 1/f noise of op-amp 6. The capacitor C_{N} 70 will be charged to compensate for the sampled kT/C noise, high-frequency noises at the output of op-amp 6, and charge injection errors.

Next, switch SW3 60 and, after a small delay, switch SW1 20 will be switched, bringing the circuitry into the signal-processing phase. When first switch SW3 60 is open, operational amplifier 5 has the configuration shown in FIG. 5C. During this phase, the kT/C noise and charge injection noise are generated at node 17 and sampled on the capacitors connected to this node. Due to the arrangement of the circuitry of operational amplifier 5, the value of sampled noise introduced will be significantly lower than in prior art configurations.

The value of the kT/C noise generated by opening SW3 60 is determined by the parallel connection of relatively large capacitor C_{NL} 75 with serially connected very small capacitor C_{N} 70 and relatively large CDS capacitor C_{CDS} 50. As a result, the generated kT/C noise will be small because of large value of C_{NL} 75.

The noise voltage introduced at node 17 by opening SW3 60 will be to a great degree attenuated at node 11 by the capacitance divider: C_{N} 70-C_{CDS} 50. This noise voltage equals the sum of sampled kT/C noise, high-frequency noises at the output of op-amp 6, and charge injection errors. The majority of this error voltage will be stored on small capacitor C_{N} 70, and an insignificant part of this error voltage will be stored on CDS capacitor C_{CDS} 50. This negligible error voltage practically will not disturb the voltage on CDS capacitor C_{CDS} 50, which will be still charged to the value of the main low frequency noises of op-amp 6: i.e., 1/f noise, and DC offset as they were sampled at the beginning of fake integration phase.

After switch SW1 20 is switched, the circuitry takes the configuration shown in FIG. 5D. The combined error charge remains trapped on capacitor C_{CDS} since the input current of op-amp 6 is zero (assuming infinite input impedance for the op-amp). Capacitor C_{CDS} behaves like a floating voltage source equal to V_{OSLFN} . In the signal-processing phase, offset and low-frequency noise compensated operational amplifier 5 is available for amplification and is connected again to the signal path, as shown in FIG. 5D.

### Exemplary Circuit Embodiment—Switching Capacitors Inverting Amplifier

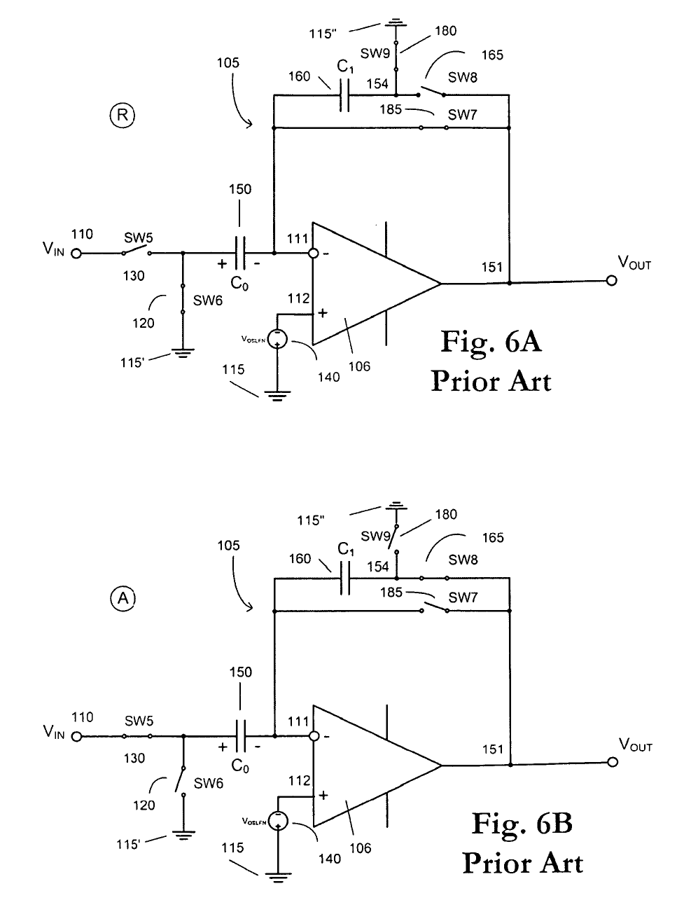

FIGS. 6A and 6B illustrate another conventional circuit—prior art switching capacitors inverting amplifier 105, which includes an op-amp 106. For simplicity, we will assume that the op-amp 106 is close to ideal, having infinite gain and infinite input impedance, but still having DC offset and internal low frequency noise. FIGS. 6A and 6B conditionally show the low-frequency noise 1/f, thermal noise, and offset of op-amp 106 as a voltage source V_{OSLFN} 140 connected between a non-inverting input 112 of op-amp 106 and a reference ground node 1 15. An inverting input 111 of op-amp 106 is connected to first terminal of a switching capacitor C₀ 150, first terminal of a switching capacitor C₁ 160, and to first terminal of a feedback switch SW7 185. Second terminal of switching capacitor C₀ 150 is connected to first terminal of switch SW6 120 and first terminal of a switch SW5 130, second terminal of which is connected to the an input 110 of amplifier 105. Second terminal of switch SW6 120 is connected to a reference ground node 115′. Second terminal of switching capacitor C1 160 is connected at a node 154 to first terminal of a switch SW9 180 and first terminal of a switch SW8 165. Second terminal of switch SW9 180 is connected to a reference ground node 115″. Second terminal of switch SW8 165 is connected to second terminal of switch SW7 185 and to an output 151 of op-amp 106, which is essentially an output of amplifier 105.

During the reset phase, depicted in FIG. 6A, switch SW5 130 and switch SW8 165 are open, switch SW6 120, switch SW7 185, and switch SW9 180 are closed, and op-amp 106 is disconnected from the signal path and connected in a unity-gain configuration by closing the switch SW7 185. Assuming the op-amp 106 has infinite gain, the voltage obtained at node 111 after op-amp 106 has settled is equal to the sum of the offset voltage and low-frequency 1/f noise of op-amp 106 V_{OSLFN} . This voltage is also equal to the voltages across switching capacitors C₀ 150 and C₁ 160.

The circuitry is then switched to the amplifier configuration, most often by first switching the circuit from the reset unity-gain configuration. To do this, switch SW7 185 is switched open. Simultaneously the operation of sample-and-hold is performed for the voltage at node 111, which is sampled and held on parallel-connected capacitors 150 and 160. While switching from the reset configuration, the opening of switch 185 also generates a kT/C noise which is also sampled on parallel-connected capacitors 150 and 160. Thus the combined error voltage sampled is equal to the sum of the offset voltage and the low-frequency 1/f noise of op-amp 106 (i.e., V_{OSLFN} ), plus an additional error from thermal noise kT/(C₀+C₁) and the charge injection error occurring when switch SW7 185 opens. The combined error charge will remain trapped on parallel-connected capacitors 150 and 160 since the input current of op-amp 106 is zero (assuming infinite input impedance), and hence parallel-connected capacitors 150 and 160 behave like a floating voltage source equal to V_{OSLFN} plus the kT/C and charge-injection error voltage. Opening of switch SW7 185 completes the reset phase of switched capacitor amplifier 105.

The second phase of CDS, the amplification phase, starts with switching the circuitry into the amplification configuration. This is done by switching amplifier 106 into the configuration shown in FIG. 6B by first opening switch SW6 120, and then closing switches SW5 130 and SW8 165. At this moment capacitor C₀ 150 will be connected in such a way that the voltage stored across it, representing the error due to the DC offset and 1/f noise, is subtracted from the input signal value, compensating for the above errors. The same voltage is stored across capacitor C1 160, bringing the voltage at the output node 151 of the amplifier 106 equal to the amplified value of input signal minus the sampled value of DC offset and 1/f noise.

As it is described above, during the amplification phase, the DC offset and 1/f noise value is subtracted from the instantaneous value of the input signal, but this value is corrupted with the value of the kT/C noise existing at the moment of sampling. While the DC offset and the 1/f noise will be compensated, the additional sampled error voltage value introduced by sampling kT/C is erroneously involved in the compensation process, introducing error into the signal path during the amplification phase.

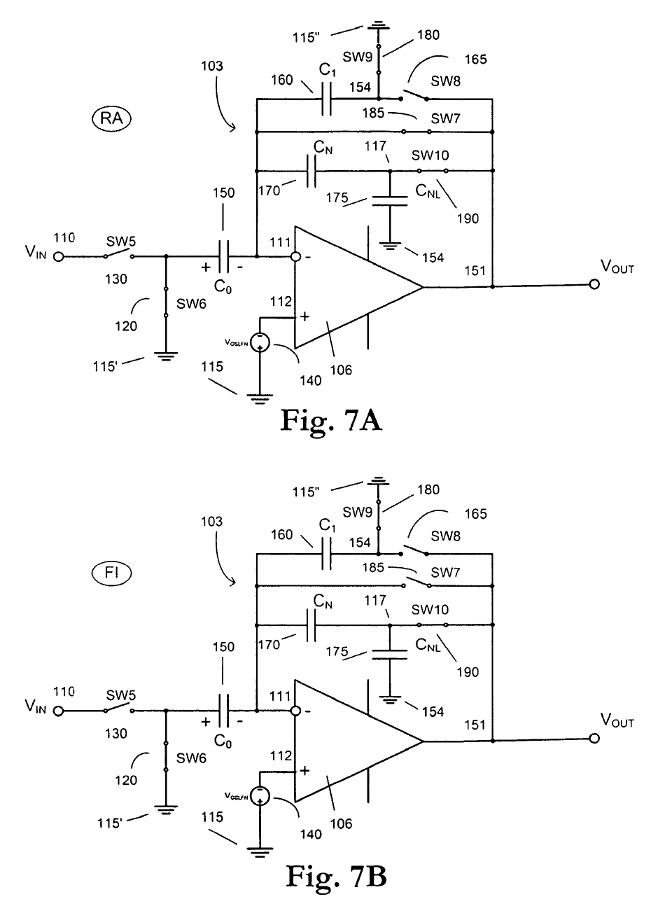

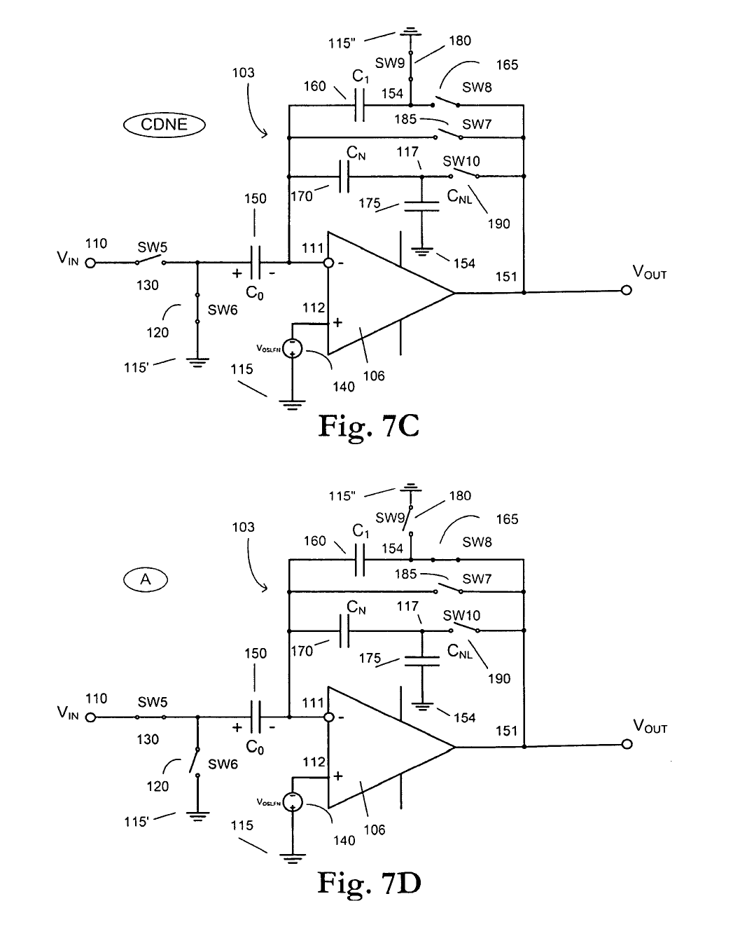

FIGS. 7A-7D present one embodiment of a circuit using a switching capacitors inverting amplifier in accord with the present invention in its different phases of operation. These figures follow FIGS. 6A-6B with the following additions. First, the output 151 of op-amp 106 is coupled by switch SW10 190 to node 117, which is connected to a “fake” integrating capacitor C_{N} 170 and to one plate of “noise load” capacitor C_{NL} 175. The other plate of “noise load” capacitor C_{NL} 175 is connected to node 154 which is at ground potential. Capacitor C_{NL} 175 is used to reduce the kT/C noise generated at node 117 during the opening of switch SW10 190. Capacitor C_{N} 170 together with parallel-connected capacitor C₀ 150 and capacitor C₁ 160 forms a capacitive divider, which attenuates the kT/C noise generated at node 117 while transmitting it to the node 111. The attenuation ratio is approximately determined by the ratio of the capacitance of C_{N} to the input capacitance of op-amp 6 at node 111 (that for an ideal op-amp 106 equals that of (C₀+C₁)). The capacitance values for capacitors C_{N} 170 and C_{NL} 175 shown in FIGS. 7A-7D can have different values. For the sizable attenuation of kT/C noise generated at node 117 the following conditions should be observed:

C_{N}<<C_{NL};

CN<<C_{CDS}.

For example, the value of capacitor C_{N} 170 can be in the range from 0.1 pF to 20 pF, and the value of capacitor C_{NL} 175 can be from 10 pF to 200 pF.

During regular operation, the amplifier 105 in FIGS. 7A-7D is switching among different phases in the following repeating order: Reset Amplifier, Fake Integration, Capacitive Division Noise Elimination, Amplification Phase, Reset Amplifier, and so on. Table 2, below, depicts the state of the switches during different phases of the operation of circuit 105. When a switch is in the ON state it is closed, when it is in the OFF state it is open.

TABLE 2

| | Switches Position | | | | | |
|---|---|---|---|---|---|---|
| | SW5 | SW6 | SW7 | SW8 | SW9 | SW10 |
| Reset | OFF | ON | ON | OFF | ON | ON |
| Amplifier | | | | | | |
| Phase | | | | | | |
| Fake | OFF | ON | OFF | OFF | ON | ON |
| Integration | | | | | | |
| Phase | | | | | | |
| Capacitive | OFF | ON | OFF | OFF | ON | OFF |
| Division Noise | | | | | | |
| Elimination | | | | | | |
| Amplification | ON | OFF | OFF | ON | OFF | OFF |
| Phase | | | | | | |

FIG. 7A shows the switching capacitors inverting amplifier 103 in reset configuration. Switch SW6 120 is closed, essentially grounding second terminal of capacitor 150. Switch SW7 185 is closed, which brings the op-amp 106 into unity-gain configuration.

Assuming the op-amp 106 has infinite gain, the voltage obtained at node 111 after op-amp 106 has settled is equal to the sum of the offset voltage and low-frequency 1/f noise of op-amp 106 V_{OSLFN} . This voltage is also equal to the voltages across switching capacitor C₀ 150 and across capacitor C₁ 160.

At the end of the reset phase switch SW7 185 is open, and amplifier 103 is switched into the fake integration configuration shown in FIG. 7B. Simultaneously an operation of sample-and-hold is performed for the voltage at node 111, which is sampled and held on parallel-connected capacitors 150 and 160. While switching from the reset configuration, the opening of switch 185 also generates a kT/C noise which is also sampled on parallel-connected capacitors 150 and 160. Thus the combined error voltage sampled is equal to the sum of the offset voltage and the low-frequency 1/f noise of op-amp 106 (i.e., V_{OSLFN} ), plus an additional error from thermal noise kT/(C₀+C₁) and the charge injection error occurring when switch SW7 185 opens. The combined error charge will remain trapped on parallel-connected capacitors 150 and 160 since the input current of op-amp 106 is zero (assuming infinite input impedance), and hence parallel-connected capacitors 150 and 160 behave like a floating voltage source equal to V_{OSLFN} plus the kT/C and charge-injection error voltage. The opening of switch SW7 185 completes the reset phase of switched capacitor amplifier 105, and starts the fake integration phase shown in FIG. 7B.

The output of the op-amp 106 during the fake integration phase is connected to its inverting input 111 through noise capacitor C_{N} 170, putting op-amp 106 in an integrator configuration with the capacitor C_{N} 170 serving as an integrating capacitor. Noise load capacitor C_{NL} 175 is connected as a capacitive load to the output of the integrator.

The main goal of the fake integration phase is the elimination of kT/C noise, high-frequency noises at the output of op-amp 106, and charge injection noise, which were all sampled during the opening of switch SW7 185 at the beginning of fake integration phase, while leaving parallel-connected capacitors 150 and 160 still charged to the value of the main low frequency noises of op-amp 106: i.e., 1/f noise and DC offset as they were sampled at the beginning of the fake integration phase.

At the beginning of the fake integration phase, the voltage difference between the inverting input 111 and non-inverting input 112 of the op-amp 106 is equal to the sampled value of the sum of DC offset, 1/f noise, kT/C noise, high-frequency noises at the output of op-amp 106, and charge injection error. Assuming that op-amp 106 has an infinite gain, at the end of the fake integration phase, the voltage difference between the inverting input 112 and non-inverting input 112 of op-amp 106 will be equal to the sampled value of the sum of DC offset and 1/f noise (i.e., V_{OSLFN} ). This essentially eliminates the additional error voltage related to the sampled kT/C noise, high-frequency noises at the output of op-amp 106, and charge injection error at node 112.

At the end of the fake integration phase the error voltage at node 111 is related only to the sum of the DC offset voltage and 1/f noise of op-amp 106. The capacitor C_{N} 170 will be charged to compensate for the sampled kT/C noise, high-frequency noises at the output of op-amp 106, and charge injection errors.

Next, switch SW10 190 and, after a small delay, switches SW6 120 and SW9 180 will be open, and then switch SW5 130 closed, bringing the circuitry into the amplification phase. When first switch SW10 190 is open, amplifier 103 has the configuration shown in FIG. 7C. During this, the kT/C noise and charge injection noise are generated at node 117 and sampled on the capacitors 150 and 160 connected to this node. Due to the arrangement of the circuitry of operational amplifier 103, the value of kT/C noise introduced and sampled will be relatively low.

The value of the kT/C noise generated by opening SW10 190 is determined by the parallel connection of relatively large capacitor C_{NL} 175 with serially-connected very small capacitor C_{N} 170 and relatively large parallel-connected capacitors 150 and 160. As a result, the generated kT/C noise will be small because of large value of C_{NL} 175.

The noise voltage introduced at node 117 by opening SW10 190 will be to a great degree attenuated at node 111 by the capacitance divider: C_{N}−(C₀+C₁). This noise voltage equals the sum of sampled kT/C noise, high-frequency noises at the output of op-amp 106, and charge injection errors. The majority of this error voltage will be stored on small capacitor C_{N} 170, and an insignificant part of this error voltage will be stored on capacitance (C₀+C₁) of parallel capacitors 150 and 160. This negligible error voltage practically will not disturb the voltage on switching capacitors 150 and 160, which will be still charged to the value of the main low frequency noises of op-amp 106: i.e., 1/f noise, and DC offset as they were sampled at the beginning of fake integration phase.

After switches SW6 120 and SW9 180 are open, the circuitry takes the configuration shown in FIG. 7D. At this moment capacitor C₀ 150 will be connected such a way, that the voltage, which is stored across it and represents the error due to the DC offset and 1/f noise, is subtracted from the input signal value, compensating for the above errors. The same voltage is stored across capacitor C1 160, that essentially brings the voltage at the output node 151 of the amplifier 106 equal to the amplified value of input signal independent of DC offset and 1/f noise.

### Exemplary Circuit Embodiment—Switched Capacitor Integrator

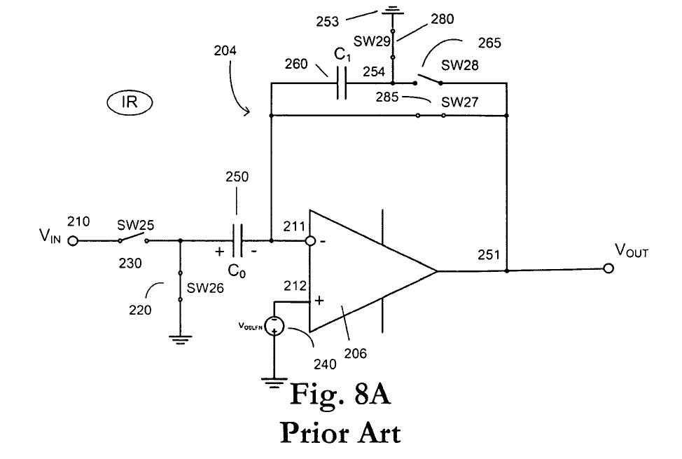

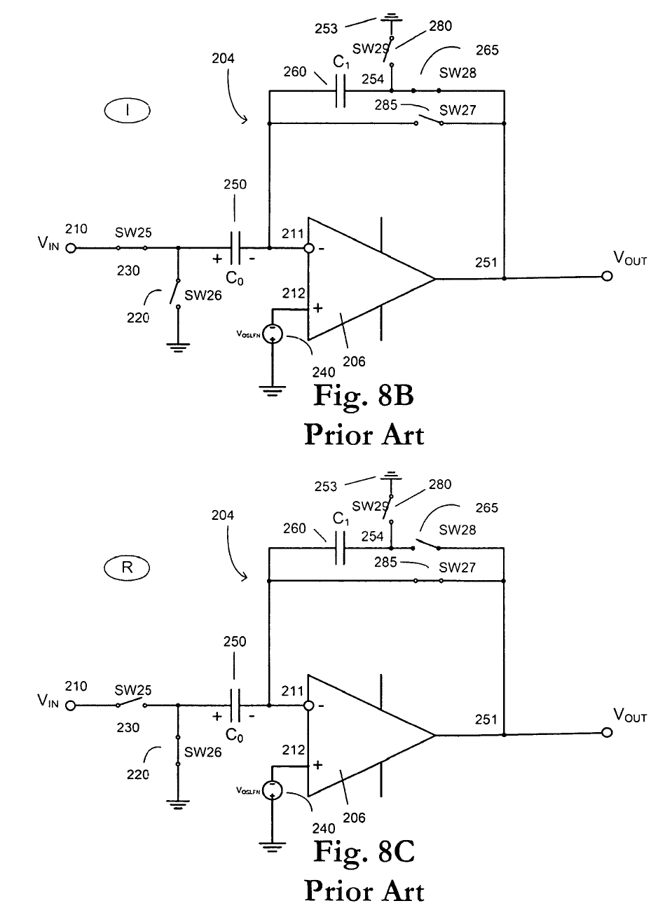

FIGS. 8A-8C illustrate another conventional circuit—prior art switching capacitor integrator 204 using CDS for DC offset and 1/f noise elimination in different phases of operation. FIG. 8A presents the switched capacitor integrator in Initial Reset Phase, FIG. 8B presents the switched capacitor integrator in Integration Phase, and FIG. 8C presents the switched capacitor integrator in Reset Phase.

As is seen from FIGS. 8A-8C, switching capacitor integrator has the same configuration as switching capacitor amplifier of FIGS. 6A-6B and differs only by different phases of operation and by positions and sequence of switches during different phases of operation.

FIGS. 8A-8C show switching capacitor integrator 204, which includes an op-amp 206. For simplicity, we will assume that the op-amp 206 is close to ideal, having infinite gain and infinite input impedance, but still having DC offset and internal low frequency noise. FIGS. 8A-8C conditionally show the low-frequency noise 1/f, thermal noise, and offset of op-amp 206 as a voltage source V_{OSLFN} 240 connected between a non-inverting input 212 of op-amp 206 and a reference ground node 215. An inverting input 211 of op-amp 206 is connected to first terminal of a switching capacitor C₀ 250, first terminal of a integrating capacitor C₁ 260, and to first terminal of a feedback switch SW27 285. Second terminal of switching capacitor C₀ 250 is connected to first terminal of switch SW26 220 and first terminal of a switch SW25 230, second terminal of which is connected to input 210 of integrator 204. Second terminal of switch SW26 220 is connected to a reference ground node 215′. Second terminal of integrating capacitor C₁ 260 is connected at a node 254 to first terminal of a switch SW29 280 and first terminal of a switch SW28 265. Second terminal of switch SW29 280 is connected to a reference ground node 215″. Second terminal of switch SW28 265 is connected to second terminal of switch SW27 285 and to an output 251 of op-amp 206, which is essentially an output of integrator 204.

In normal operation, switched capacitor integrator starts in the Initial Reset Phase, this is essentially the reset phase for the CDS process, followed by alternating Integration Phases and Reset Phases, during which the compensation of DC offset and 1/f low frequency noise takes place using CDS.

During the Initial Reset Phase, depicted in FIG. 8A, switch SW25 230 and switch SW28 265 are open; switch SW26 220, switch SW27 285, and switch SW29 280 are closed, and op-amp 206 is disconnected from the signal path and connected in a unity-gain configuration by closing the switch SW27 285. Assuming the op-amp 206 has infinite gain, the voltage obtained at node 211 after op-amp 206 has settled is equal to the sum of the offset voltage and low-frequency 1/f noise of op-amp 206 V_{OSLFN} . This voltage is also equal to the voltages across capacitors C₀ 250 and C₁ 260.

Upon finishing initial reset phase integrator 204 is then switched to the integrator configuration, most often by first switching the circuit from the reset unity-gain configuration. To do this, switch SW27 285 is switched open. Simultaneously the operation of sample-and-hold is performed for the voltage at node 211, which is sampled and held on parallel-connected capacitors 250 and 260. While switching from the initial reset configuration, the opening of switch 285 also generates a kT/C noise which is also sampled on parallel-connected capacitors 250 and 260. Thus the combined error voltage sampled is equal to the sum of the offset voltage and the low-frequency 1/f noise of op-amp 206 (i.e., V_{OSLFN} ), plus an additional error from thermal noise kT/(C₀+C₁) and the charge injection error occurring when switch SW27 285 opens. The combined error charge will remain trapped on parallel-connected capacitors 250 and 260 since the input current of op-amp 206 is zero (assuming infinite input impedance), and hence parallel-connected capacitors 250 and 260 behave like a floating voltage source equal to V_{OSLFN} plus the kT/C and charge-injection error voltage. Opening of switch SW29 280 completes the initial reset phase of switched capacitor integrator 204. Switch SW29 280 stays open through the rest of the operation of integrator 204. As can be seen from the further discussion, sampling and storing the DC offset and 1/f noise error on integrating capacitor 260 is the only difference between the Initial Reset Phase and Reset Phase.

The rest of the operation of integrator 204 is composed of an infinite sequence of alternating Integration Phases and Reset Phases, during which the compensation of DC offset and 1/f low frequency noise takes place using CDS. The Integration Phase starts with switching the circuitry into the integrator configuration. This is done by switching integrator 204 into configuration shown in FIG. 8B by first opening switch SW26 220, and then closing switches SW28 265 and SW25 230. At this moment capacitor C₀ 250 will be connected such that the voltage, which is stored across it and represents the error due to operational amplifier DC offset and low frequency 1/f noise is subtracted from the input signal value, compensating for the above errors. The same voltage is stored across capacitor C₁ 260, bringing the initial (before first integration phase) voltage at the output node 251 of the amplifier 206 equal to reference ground potential, compensating for the DC offset and 1/f noise.

During the Integration Phase, the voltage equal to the current value of the input signal minus the error voltage value sampled on capacitor 250 is integrated on integrating capacitor C1 260. At the end of the Integration Phase the integrator is settled and the potential at node 211 is equal to the virtual ground, which is real ground potential plus DC offset and 1/f noise.

At the end of the Integration Phase first the switches SW25 230 and SW28 265 are open. Following this, switch SW26 220 and then SW27 285 are closed bringing the circuitry into the Reset Phase. During the Reset Phase, depicted in FIG. 8C, op-amp 206 is disconnected from the signal path and connected in a unity-gain configuration. Assuming the op-amp 206 has infinite gain, the voltage obtained at node 211 after op-amp 206 has settled is equal to the sum of the offset voltage and low-frequency 1/f noise of op-amp 206 V_{OSLFN} . This voltage is also equal to the voltage across capacitor C₀ 250.

The next time integrator 204 is switched from the Reset Phase to the Integration Phase, it is done by first switching the circuit from the reset unity-gain configuration. To do this, switch SW27 285 is switched open. Simultaneously the operation of sample-and-hold is performed for the voltage at node 211, which is sampled and held on capacitor 250. The voltage on integrating capacitor 260 is held intact during this switching. The opening of switch 285 also generates a kT/C noise which is also sampled on capacitor 250. Thus the combined error voltage sampled is equal to the sum of the offset voltage and the low-frequency 1/f noise of op-amp 206 (i.e., V_{OSLFN} ), plus an additional error from thermal noise kT/(C₀+C₁) and the charge injection error occurring when switch SW27 285 opens. While the DC offset and the kT/C noise will be compensated during the Integration Phase, the additional sampled error voltage value introduced by sampling kT/C is erroneously involved in the compensation process, introducing error into the final integration results.

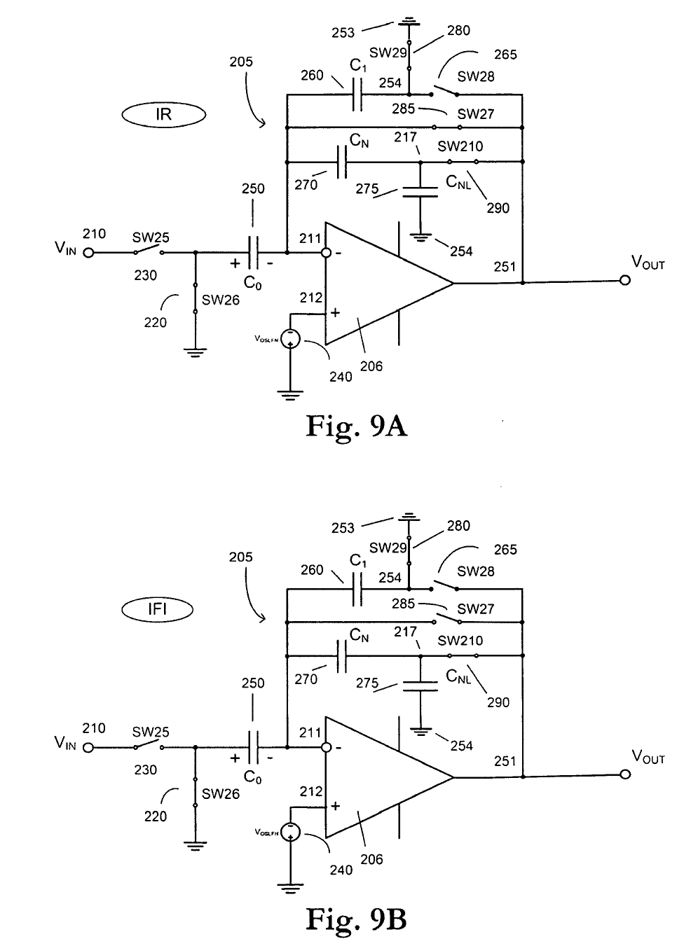

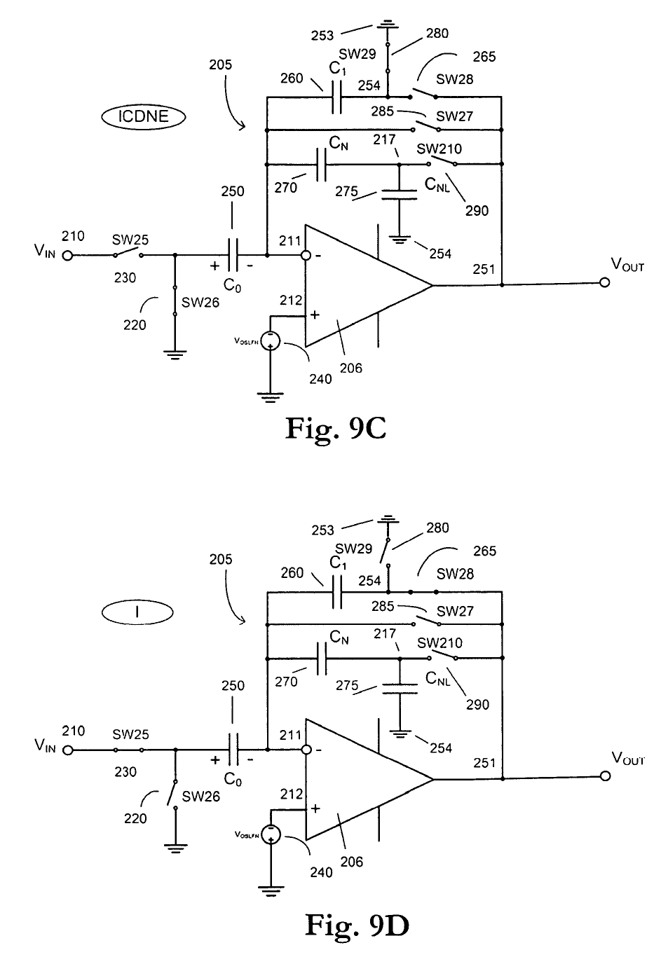

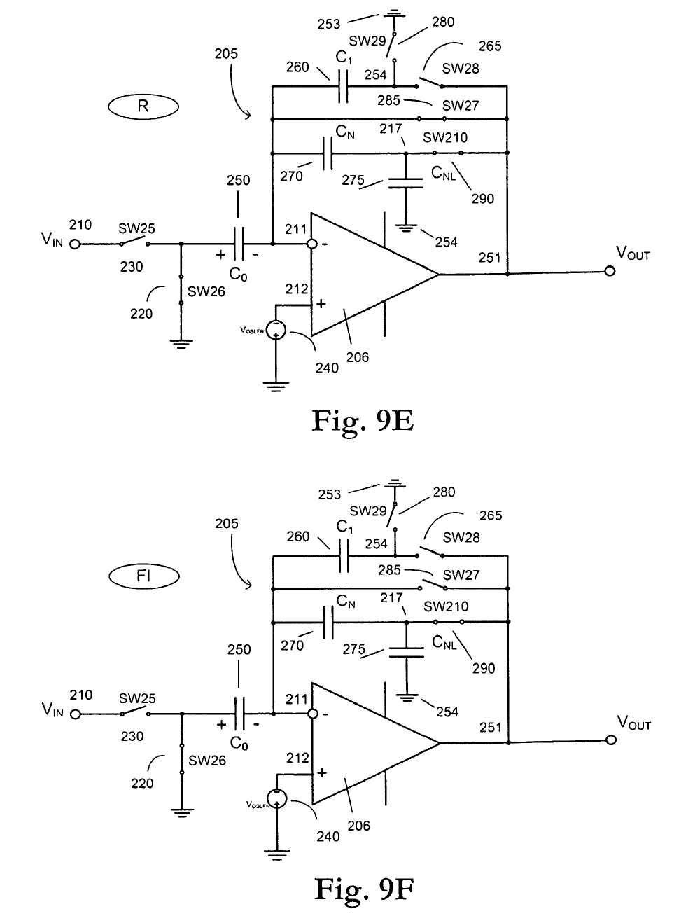

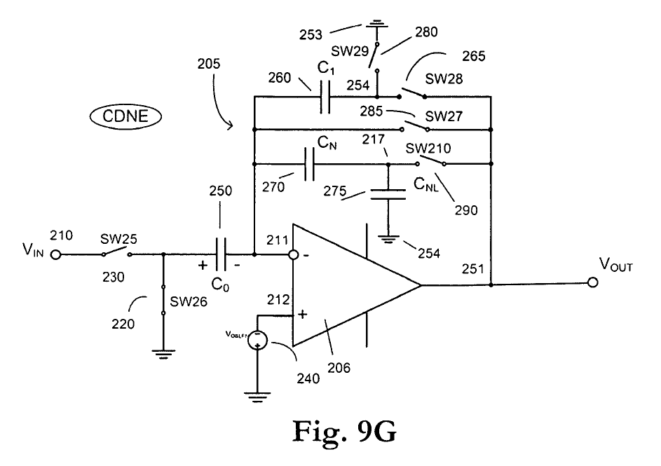

FIGS. 9A-9G present one embodiment of a circuit using a switching capacitors integrator in accord with the present invention in its different phases of operation. These figures follow FIGS. 8A-8C with the following additions. First, the output 251 of op-amp 206 is coupled by switch SW210 290 to node 217, which is connected to a “fake” integrating capacitor C_{N} 270 and to one plate of “noise load” capacitor C_{NL} 275. The other plate of “noise load” capacitor C_{NL} 275 is connected to node 254 which is at ground potential. Capacitor C_{NL} 275 is used to reduce the kT/C noise generated at node 217 during the opening of switch SW210 290. Capacitor C_{N} 270 together with parallel-connected capacitor C₀ 250 and capacitor C₁ 260 form a capacitive divider, which attenuates the kT/C noise generated at node 217 while transmitting it to the node 211. The attenuation ratio is approximately determined by the ratio of the capacitance of C_{N} to the input capacitance of op-amp 206 at node 211 (that for ideal op-amp 206 equals that of (C₀+C₁)). The capacitance values for capacitors C_{N} 270 and C_{NL} 275 shown in FIGS. 9A-9F can have different values. For the sizable attenuation of kT/C noise generated at node 217 the following conditions should be observed:

C_{N}<<C_{NL};

C_{N}<<C_{CDS}.

For example, the value of capacitor C_{N} 270 can be in the range from 0.1 pF to 20 pF, and the value of capacitor C_{NL} 275 can be from 10 pF to 200 pF.

During regular operation, integrator 205 is switching among different phases in the following repeating order: Initial Reset, Initial Fake Integration, Initial Capacitive Division Noise Elimination, Integration Phase, Reset Phase, Fake Integration Phase, Capacitive Division Noise Elimination, Integration Phase, and so on. Table 3, below, depicts the state of the switches during different phases of the operation of circuit 205. When a switch is in the ON state it is closed, when it is in the OFF state it is open.

TABLE 3

| | Switches Position | | | | | |
|---|---|---|---|---|---|---|
| | SW25 | SW26 | SW27 | SW28 | SW29 | SW210 |
| Initial Reset | OFF | ON | ON | OFF | ON | ON |
| Phase, FIG. 9A | | | | | | |
| Initial Fake | OFF | ON | OFF | OFF | ON | ON |
| Integration | | | | | | |
| Phase, FIG. 9B | | | | | | |
| Initial | OFF | ON | OFF | OFF | ON | OFF |
| Capacitive | | | | | | |
| Division Noise | | | | | | |
| Elimination, | | | | | | |
| FIG. 9C | | | | | | |
| Integration | ON | OFF | OFF | ON | OFF | OFF |
| Phase, FIG. 9D | | | | | | |
| Reset Phase, | OFF | ON | ON | OFF | OFF | ON |
| FIG. 9E | | | | | | |
| Fake | OFF | ON | OFF | OFF | OFF | ON |
| Integration | | | | | | |
| Phase, FIG. 9F | | | | | | |
| Capacitive | OFF | ON | OFF | OFF | OFF | OFF |
| Division Noise | | | | | | |
| Elimination, | | | | | | |
| FIG. 9G | | | | | | |

As is seen from FIG. 9A-9G, switching capacitor integrator 205 has the same configuration as the proposed switching capacitor amplifier of FIG. 7A-7D and differs only by different phases of operation and the positions and sequence of switches during different phases of operation.

The operation of integrator 205 during the first four phases: Initial Reset, Initial Fake Integration, Initial Capacitive Division Noise Elimination, and Integration Phase, is identical to the operation of the proposed switching capacitor amplifier of FIGS. 7A-7D during its four phases of operation: Reset Amplifier, Fake Integration, Capacitive Division Noise Elimination, Amplification Phase, respectively.

The following three phases of operation of integrator 205: Reset Phase, Fake Integration Phase, Capacitive Division Noise Elimination, are identical to the operation of the proposed switching capacitor amplifier of FIG. 7A-7D during its following phases of operation: Reset Amplifier, Fake Integration, and Capacitive Division Noise Elimination respectively, with the exception that switch SW29 280 is constantly open. This prevents the discharge of the integrating capacitor 260 during the operation of integrator 205.

As is evident from the above description, embodiments of the current invention use correlated double sampling to compensate for DC offset and low frequency noises of the operational amplifier, and fake integration and the use of a capacitor divider to eliminate or significantly reduce kT/C noises and charge injections which emerged during the opening of internal switches and were sampled by different internal capacitors. Such elimination or significant reduction takes place when any switch in the circuitry is opened and kT/C noise is sampled on a capacitor. In the proposed arrangement, every kT/C noise error is eliminated or significantly reduced.

### Exemplary Circuit Embodiment—Switched Capacitor Integrator with Reduction of Non-Infinite Gain Effects

As discussed above for all embodiments of the invention, the fake integration phase eliminates the large kT/C noise introduced at the end of the Reset or Initial Reset phase from the opening of the switch putting the circuit into an appropriate feedback configuration (for example, in a unity-gain configuration) during the (Initial) Reset phase. The magnitude of this noise at the inverting input of the op-amp (i.e., V_{akTC}) is comparably large. During the fake integration phase, the integration of this noise resulted in the change of the output voltage of the op-amp by:

ΔV_{FI}=V_{akTC}*K,

where K is the division ratio of the capacitive divider:

K=C_{II}/C_{N}

where C_{II} is the total capacitance at the inverting input of op-amp. For different embodiments C_{II} has different values. For the embodiment shown in FIGS. 5A-5D, C_{II} is equal to the capacitance of capacitor 50. For the embodiment shown in FIGS. 7A-7D, C_{II} is equal to the sum of capacitances of capacitors 150 and 160. For the embodiment shown in FIGS. 9A-9G, C_{II} is equal to the sum of capacitances of capacitors 250 and 260.

If the op-amp were ideal and had infinite gain, this change in the output voltage would have no influence on the CDS process. But since the op-amp has finite gain G, this will result in the introduction of the additional error voltage accumulated on the CDS capacitance at the end of the fake integration phase, which is equal to:

ΔV_{ER}=ΔV_{FI}/G=V_{akTC}*K/G

This error voltage is stored on all capacitors involved in CDS compensation.

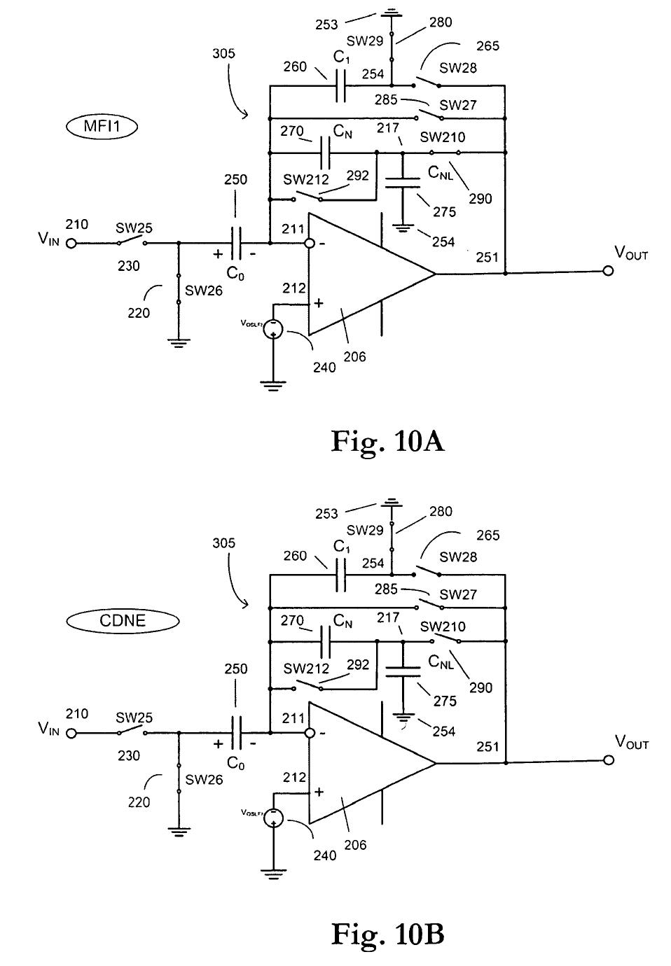

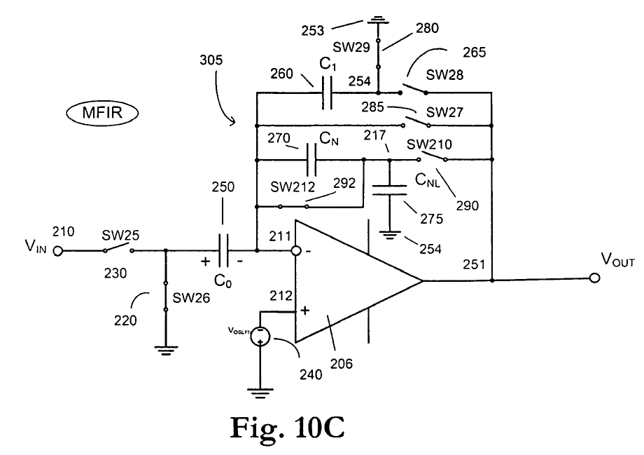

To reduce the value of this error, consider another embodiment of a switched capacitor integrator 305, shown in FIGS. 10A-10C. In this embodiment, additional sub-phases of the fake integration process are used. Each additional sub-phase of fake integration is preceded by an additional fake integration capacitor reset sub-phase. During the fake integration capacitor reset sub-phase, the fake integration capacitor is reset by shorting it with a special switch. The opening of this switch does not introduce any kT/C error into the resulting voltage on the CDS capacitor because at the moment of generation of kT/C noise the integrator 305 is in open loop configuration, and all errors induced in this state will be eliminated by integrator in closed loop configuration.

The switched capacitor integrator 305 is essentially identical to the switched capacitor integrator 205 shown in FIGS. 9A-9F, but additionally contains switch SW212 292, the first terminal of which is connected to the node 211, and the second terminal of which is connected to node 217.

During its operation, integrator 305 passes through the following sequence of the operational phases: Initial Reset, Initial Multiple Fake Integration, Integration Phase, Reset Phase, Multiple Fake Integration Phase, Integration Phase, and so on.

The operation of switched capacitor integrator 305 shown in FIGS. 10A-10C is essentially identical to the operation of the switched capacitor integrator 205 shown in FIGS. 9A-9F in all phases, except the Initial Multiple Fake Integration Phase that replaces the Initial Fake Integration Phase and Initial Capacitive Division Noise Elimination state of integrator 205, and the Multiple Fake Integration Phase that replaces the Fake Integration Phase and Capacitive Division Noise Elimination state of integrator 205. Each of these new phases is composed of the particular sequence of sub-phases identified below.

Table 4, below, depicts the sequence of sub-phases and the states and position of the switches during the sub-phases of the operation of circuit 305, which comprise the Initial Multiple Fake Integration Phase of circuit 305. Please, note that sub-sequence of following 4 sub-phases and states: Initial Multiple Fake Integration Reset sub-Phase 1—Initial Capacitive Division Noise Elimination 2—Initial Multiple Fake Integration sub—Phase 2—Initial Capacitive Division Noise Elimination 3 can be repeated a few times in sequence. When a switch is in the ON state it is closed, when it is in the OFF state it is open.

TABLE 4

| Sub-Phase or state | FIG. | SW25 | SW26 | SW27 | SW28 | SW29 | SW210 | SW212 |
|---|---|---|---|---|---|---|---|---|
| Initial Multiple Fake | FIG. 10A | OFF | ON | OFF | OFF | ON | ON | OFF |
| Integration sub- | | | | | | | | |
| Phase 1 | | | | | | | | |
| Initial Capacitive | FIG. 10B | OFF | ON | OFF | OFF | ON | OFF | OFF |
| Division Noise | | | | | | | | |
| Elimination 1 | | | | | | | | |
| Initial Multiple Fake | FIG. 10C | OFF | ON | OFF | OFF | ON | OFF | ON |
| Integration Reset | | | | | | | | |
| sub-Phase 1 | | | | | | | | |
| Initial Capacitive | FIG. 10B | OFF | ON | OFF | OFF | ON | OFF | OFF |
| Division Noise | | | | | | | | |
| Elimination 2 | | | | | | | | |
| Initial Multiple Fake | FIG. 10A | OFF | ON | OFF | OFF | ON | ON | OFF |
| Integration sub- | | | | | | | | |
| Phase 2 | | | | | | | | |
| Initial Capacitive | FIG. 10B | OFF | ON | OFF | OFF | ON | OFF | OFF |
| Division Noise | | | | | | | | |
| Elimination 3 | | | | | | | | |

Table 5, below, depicts the position of the switches during sub-phases of the operation of circuit 305, which comprise the Multiple Fake Integration Phase of circuit 305. Please, note that sub-sequence of sub-phases: Multiple Fake Integration Reset sub-Phase 1—Capacitive Division Noise Elimination 2—Multiple Fake Integration sub-Phase 2—Capacitive Division Noise Elimination 3—can be repeated a few times in sequence. When a switch is in the ON state it is closed, when it is in the OFF state it is open.

TABLE 5

| | Switches Position | | | | | | |
|---|---|---|---|---|---|---|---|
| | SW25 | SW26 | SW27 | SW28 | SW29 | SW210 | SW212 |
| Multiple Fake | OFF | ON | OFF | OFF | OFF | ON | OFF |
| Integration sub- | | | | | | | |
| Phase 1 | | | | | | | |
| Capacitive Division | OFF | ON | OFF | OFF | OFF | OFF | OFF |
| Noise Elimination 1 | | | | | | | |
| Multiple Fake | OFF | ON | OFF | OFF | OFF | OFF | ON |
| Integration Reset | | | | | | | |
| sub-Phase 1 | | | | | | | |
| Capacitive Division | OFF | ON | OFF | OFF | OFF | OFF | OFF |
| Noise Elimination 2 | | | | | | | |
| Multiple Fake | OFF | ON | OFF | OFF | OFF | ON | OFF |
| Integration sub- | | | | | | | |
| Phase 2 | | | | | | | |
| Capacitive Division | OFF | ON | OFF | OFF | OFF | OFF | OFF |
| Noise Elimination 3 | | | | | | | |

The operation of integrator 305 in all phases, but the Initial Multiple Fake Integration Phase and the Multiple Fake Integration Phase, is exactly the same as operation of integrator 205 in FIG. 9A-9G. The operation of integrator 305 in Initial Multiple Fake Integration sub—Phase 1 and Initial Multiple Fake Integration sub-Phase 2 is equal to the operation of integrator 205 in Fake Integration Phase and Capacitive Division Noise Elimination state.

Continuing the discussion of the operation of integrator 305 starting with the Multiple Fake Integration Reset Sub-Phase 1, the opening of the switch SW27 285 at the end of the Reset or Initial Reset phases introduces kT/C noise V_{kTC} that is sampled on capacitors 250 and 260 to the sum of DC offset and 1/f noise of op-amp 206. This additional error voltage is reduced with the help of fake integration process.

In actuality, op-amp 206 is not ideal and has a finite gain. As discussed above, after op-amp 205 is settled during Initial Multiple Fake Integration Sub-Phase 1, capacitors 250 and 260 store the voltage equal to the sum of DC offset and 1/f noise of op-amp 206 plus the additional error voltage ΔV_{ER}=V_{akTC}*K/G, which is the result of the integration of kT/C noise on an integrator with finite gain. By choosing the parameters of the circuit such a way that K/G<<1 the value of this additional error voltage is significantly reduced but still can be sizeable.

At the end of the fake integration process, fake integration capacitor 270 will be charged. The charge on it is a part of the charge due to kT/C noise sampled on parallel capacitors 250 and 260 that later accumulated on capacitor 270 during fake integration.

During the Initial Multiple Fake Integration Reset Sub-Phase 1 (FIG. 10C), the fake integration capacitor 270 is reset by shorting it by closing switch SW212 292. The opening of this switch at the end of reset, which brings the integrator 305 into Initial Capacitive Division Noise Elimination 2 state, does not introduce any kT/C error into the voltage on capacitors 250 or 260 because at the moment of generation of kT/C noise the integrator 305. is in open loop configuration, and all errors induced in this state will be eliminated by integrator in closed loop configuration.

After the fake integration capacitor 270 is reset, additional fake integration is performed by switching integrator 305 into Initial Multiple Fake Integration Sub-Phase 2 (FIG. 10A). As a result of additional fake integration, the additional error voltage accumulated on capacitors 250 and 260 at the end of the first additional fake integration phase will be equal to:

ΔV_{ER1}=ΔV_{ER}*K/G=V_{akTC}*(K/G)²

which further eliminates the kT/C noise component in CDS process.

Opening switch SW212 292 brings the circuitry into Initial Capacitive Division Noise Elimination 3 state (FIG. 10B) and finishes Initial Multiple Fake Integration Phase.

The operation of the device in Multiple Fake Integration Phase is similar to the operation of the device in Initial Multiple Fake Integration Phase, except for the position of switch SW29 180, which is open through the whole phase.

This operation reduces the error in CDS compensation voltage introduced by the non-ideal finite gain value of op-amp 206 during the fake integration process. The proposed enhancement can be used with all embodiments of the proposed invention considered above as well as other implementations of the fake integration method.

It will therefore be seen that the foregoing represents a highly advantageous approach to correlated double sampling compensated circuits. The terms and expressions employed herein are used as terms of description and not of limitation and there is no intention, in the use of such terms and expressions, of excluding any equivalents of the features shown and described or portions thereof and it is recognized that various modifications are possible within the scope of the invention claimed.

What is claimed is:

1. A method for reducing non-ideal effects in correlated double sampling compensated circuits, the method comprising:
(a) providing a circuit comprising an operational amplifier;
(b) putting said circuit in an auto-zeroing configuration;
(c) sampling a signal comprising a sum of low frequency noises, high frequency noises, and a constant offset in connection with a sampling phase of a correlated double sampling operation;
(d) putting said circuit in a fake integration configuration and performing a fake integration, removing said high frequency noises from said sum; and
(e) putting said circuit in a signal processing configuration and simultaneously performing the second phase of said correlated double sampling operation to remove said low frequency noises and said constant offset from a produced output signal.

2. The method of claim 1 wherein putting said circuit in said auto-zeroing configuration comprises putting the circuit in a unity-gain feedback configuration.

3. The method of claim 1 wherein putting said circuit in said auto-zeroing configuration comprises putting the circuit in an error-sampling configuration.

4. The method of claim 1 wherein putting said circuit in said signal processing configuration comprises the generation of thermal high frequency noise.

5. The method of claim 1 wherein providing a circuit comprising an operational amplifier comprises providing a circuit comprising an operational amplifier, a first capacitor used for sampling, a second capacitor used for said fake integration, and a switch for putting said circuit into said fake integration configuration

6. The method of claim 5 wherein putting said circuit into said signal processing configuration produces a thermal noise that is attenuated by a capacitor divider formed by said first capacitor and said second capacitor.

7. A method for reducing non-ideal effects in correlated double sampling compensated circuits, the method comprising:
(a) providing a circuit comprising an operational amplifier, a first capacitor used for sampling, a second capacitor for fake integration, and a switch for putting said circuit into a fake integration configuration;
(b) putting said circuit in an auto-zeroing configuration;
(c) sampling a signal comprising a sum of low frequency noises, high frequency noises, and a constant offset in connection with a sampling phase of a correlated double sampling operation;
(d) putting said circuit in said fake integration configuration and performing a fake integration, removing said high frequency noises from said sum;
(e) resetting said second capacitor;
(f) putting said circuit in said fake integration configuration and performing said fake integration; and
(g) putting said circuit in a signal processing configuration and simultaneously performing the second phase of said correlated double sampling operation to remove said low frequency noises and said constant offset from a produced output signal.

8. The method of claim 7 further comprising: (h) iterating, at least once, (e) and (f).

9. A circuit comprising:
an input terminal, an output terminal, and an operational amplifier having an inverting input, a non-inverting input, a ground terminal, and an output in electrical communication with said output terminal;
a first switch having a first terminal in electrical communication with said input terminal of said circuit and a second terminal;
a second switch having a first terminal in electrical communication with said non-inverting input of said operational amplifier, and a second terminal in electrical communication with said ground terminal;
a first capacitor for a correlated double sampling operation having a first terminal in electrical communication with said non-inverting input of said operational amplifier and a second terminal in electrical communication with said second terminal of said first switch;
a third switch having a first terminal in electrical communication with said output of said operational amplifier and a second terminal; and
a second capacitor for fake integration having a first terminal in electrical communication with said non-inverting input of said operational amplifier and a second terminal in electrical communication with said second terminal of said third switch.

10. The circuit of claim 9 wherein the value of said second capacitor for fake integration is substantially smaller than the value of said first capacitor for the correlated double sampling operation.

11. The circuit of claim 9 further including a third capacitor for reducing the thermal noise from the opening of said third switch, the third capacitor having a first terminal in electrical communication with said second terminal of said second capacitor and a second terminal in electrical communication with said ground terminal.

12. The circuit of claim 11 wherein the value of said third capacitor is substantially larger than the value of said second capacitor.

13. The circuit of claim 9 further including a fourth switch having a first terminal in electrical communication with said first terminal of said second capacitor and a second terminal in electrical communication with said second terminal of said second capacitor.

14. The circuit of claim 9 wherein the circuit is operated as a correlated double sampling compensated operational amplifier.

15. The circuit of claim 9 wherein the circuit is operated as a correlated double sampling compensated switching capacitors inverting amplifier.

16. The circuit of claim 9 wherein the circuit is operated as a correlated double sampling compensated switched capacitor integrator.
